(19) United States
(12) Patent Application Publication
(10) Pub. No.: US 2002/0163361 A1
(43) Pub. Date: Nov. 7, 2002

(54) Source synchronous I/O without synchronizers using temporal delay queues

(76) Inventor: Michael W. Parkin, Palo Alto, CA (US)

Correspondence Address: ROSENTHAL & OSHA L.L.P. / SUN, 1221 MCKINNEY, SUITE 2800, HOUSTON, TX, 77010, US

(21) Appl. No.: 09/850,366

(22) Filed: May 7, 2001

(51) Int. Cl. H03K 19/00

(52) U.S. Cl. 326/93

(57) ABSTRACT

The present invention is a method and apparatus for synchronizing source I/O without synchronizers using temporal delay queues. A TDQ is used to store the incoming data in phase with a local clock instead of synchronizers. The latency for the entire system is defaulted to the maximum value supported by the system, which ensures that erroneous data is not written after error-free data is read. In one embodiment, run mode data still in transit is preserved when the switch is made by the IOB from run to control mode. Since a pull model is used, valid data is always presented on the IOB interface during run mode. Since the system is source synchronous, the receive data is written into a register using the Send clk instead of the local clock.

### BACKGROUND OF THE INVENTION

1. Field of the Invention

The present invention relates primarily to the field of hardware, and in particular to a method and apparatus for synchronizing source I/O without synchronizers using temporal delay queues.

Portions of the disclosure of this patent document contains material that is subject to copyright protection. The copyright owner has no objection to the facsimile reproduction by anyone of the patent document or the patent disclosure as it appears in the Patent and Trademark Office file or records, but otherwise reserves all rights whatsoever.

2. Background Art

The need to accomplish a task quickly on a computer is handicapped primarily by delays in transferring the data from one component of the computer to another. A computer is made up of many parts, some integral to the computer, while others are peripheral devices attached to the computer. These devices are commonly termed input/output devices, or simply I/O devices. Integral parts of the computer include, for instance, gates, flip-flops, latches, and data paths. These integral parts are controlled by a clock. Information enters and leaves these integral parts only at fixed intervals commonly termed clock cycles. Each component has its own delay time associated with its clock cycle. Since these components are not synchronous with each other, there is a delay associated with information either being written faster than can be read out, or information being read faster than it is written. One common method used to synchronize these components to minimize additional delay associated with synchronizing is with the help of synchronizers.

Synchronizer

To translate the asynchronous input to a synchronous signal that can be used to change the state of a system, a synchronizer is used. The input signals of a synchronizer are a clock and the asynchronous signal, and whose output is a signal synchronous with the input clock. Synchronizers suffer from synchronizer failure, which is the condition when the output of a flip-flop is seen by some logic blocks as a zero, and by others as a one. This occurs because the state of these logic devices changes continuously during a given clock cycle. In a purely synchronous system, synchronizer failure can be avoided by ensuring that the set-up and hold times for a flip-flop or latch are always met, but this is impossible when the input is asynchronous. Instead, the only solution possible is to wait long enough before looking at the output of the flip-flop to ensure that its output is stable, and that it has exited the metastable state, if it ever entered it.

The probability that the flip-flop will stay in the metastable state decreases exponentially, so after a very short time the probability that the flip-flop is in a metastable state is very low; however, the probability never reaches zero. For most flip-flop designs, waiting for a period that is several times longer than the set-up time makes the probability of synchronization failure very low. If the clock rate is longer than the potential metastable period, then a safe synchronizer can be built with two D flip-flops, as illustrated in FIG. 1. Here, asynchronous data is clocked at the input of Flip-flop 1. The output of Flip-flop 1 is clocked as the input for Flip-flop 2 by the same clock that clocks data for Flip-flop 1. The output of Flip-flop 2 will be synchronous as long as the combined latency of both the Flip-flops is less than the clock cycle. If the latency of the Flip-flops is less than the clock cycle, the output of Flip-flop 1 may still be in a metastable state, but since this output has to go through another Flip-flop (Flip-flop 2), the final output is guaranteed to be stable. But the use of two Flip-flops increases the overall latency of the system, especially when there are several of these dual Flip-flop combinations throughout the system.

I/O Device

A computer has several separate components that are joined together to create what is commercially termed as a desktop computer. Some of these devices, like the keyboard and mouse, are input devices, while others like the monitor and printer, are output devices. As the name suggests, an input device is one via which the user can put in data or information. In an input device, data flows from the user to the computer. On the other hand, an output device, as the name suggests, is a device via which the information input by the user is analyzed by the computer and the results are sent back to the user.

I/O devices are incredibly diverse. Three main characteristics are useful in organizing this wide variety, namely:

Behavior: Input (read once), output (write only, cannot be read), or storage (can be reread and usually rewritten).

Partner: Either a human or a machine is at the other end of the I/O device, either feeding data on input or reading data on output.

Data rate: The peak rate at which data can be transferred between the I/O device and the main memory or processor. For example, a keyboard is an input device used by a human with a peak data rate of about 10 bytes/second, while a laser printer is an output device with a peak data rate of about 20,000 bytes/second.

Since these I/O devices are used and operated by humans, there is an inherent delay caused by them, which adds to the limitations of the device itself. Sometimes I/O devices cause a delay because of their proximity from the main processing unit. Very often the output device, like a printer, is placed in a room far from the input device, like a keyboard. This situation is normally encountered in offices where a cable carries the data from the keyboard to the printer, and there is an additional delay due to the processing limitation of the cable.

It is clearly seen that a lot of time is wasted in not only synchronizing the plethora of integral parts like Flip-flops, gates, and latches, but also other peripheral devices that are common in present computing environments. As seen earlier, by trying to ensure non-metastable data in case of a flip-flop or latch, if a system uses two D flip-flops for every instance were data has to be passed onto the next component in a timely fashion, there is additional delay. Similarly, I/O devices have not only inherent delays, for example, due to their proximity from the main processing unit, but delays caused by the users of the I/O devices, who are mainly humans.

Take for instance a computer system that is massively parallel. In such a system, the integral parts might be arranged as follows. There might be many CPUs each connected together along with an interface (sometimes termed a main cluster interface (MCI)) to form an ASIC (Application Specific Integrated Circuit) chip. In turn, many ASIC chips might be connected on a board. Each board might be connected to another board by a backpane connector, and so on. With so many connected integral parts in a system such as this, there is a need to reduce the delays not caused by humans, i.e. the synchronization delays caused by integral parts.

### SUMMARY OF THE INVENTION

The present invention provides a method and apparatus for synchronizing source I/O without synchronizers using temporal delay queues. In one embodiment, a temporal delay queue (TDQ) is used to store incoming data and present it to the receiving interface in phase with the local clock instead of synchronizers. The TDQ logic will present a fixed latency between a sending I/O block (IOB) and the output of the receiving TDQ. This means that both the sending IOB and the receiving TDQ have the same clock frequency, but can vary in phase. This TDQ logic is initialized at power on reset, or by the assertion of a signal. In yet another embodiment, the maximum value supported by the hardware is set as the default latency for the entire IOB. This ensures that erroneous data is not written after error-free data is read. Software using control mode can program the TDQ logic to adjust for various chip-to-chip latencies throughout the IOB.

In another embodiment, the run mode data still in transit is preserved even after the IOB switches from run to control mode. In another embodiment, since the IOB uses a pull model of data transmission, as opposed to a push model, valid data is always presented on the IOB interface while in run mode. This means that the valid bit cannot be used to write data into a receiving TDQ.

In another embodiment, any one of the two clock edges in a system clock signal is used to clock the data. In another embodiment, both clock edges in a system clock signal are used to clock the data. In yet another embodiment, two new signals are added to the IOB interface. They are : Send_clk and Remote_run signals. If both edges of the system clock signal are used , then the Send_clk signal is one half the frequency of the system clock signal so that it is no greater than the maximum data rate. If, on the other hand, just one clock edge is used, then the Send_clk signal is equal to the frequency of the system clock signal making it no greater than the maximum data rate. Since the system is source synchronous, the receive data is written into a register using the Send_clk instead of the conventional local clock.

### BRIEF DESCRIPTION OF THE DRAWINGS

These and other features, aspects and advantages of the present invention will become better understood with regard to the following description, appended claims and accompanying drawings where:

FIG. 1 is an illustration of a synchronizer.

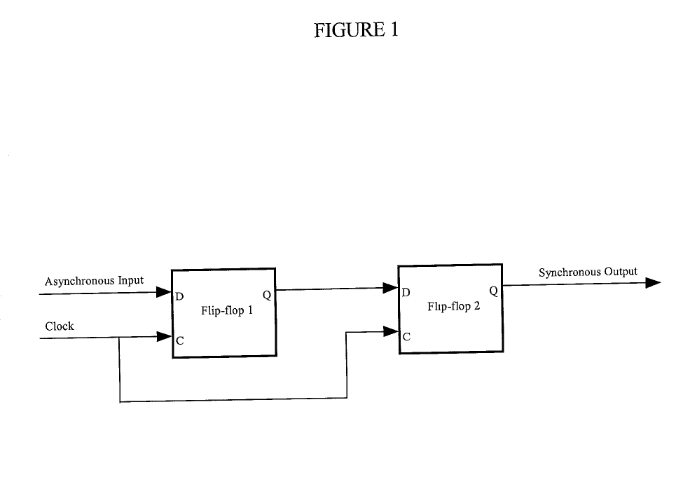

FIG. 2 is an illustration of a TDQ.

FIG. 3A is an illustration of a TDQ logic using a rising edge clock.

FIG. 3B is an illustration of a TDQ logic using a rising and negative edge clock.

FIG. 4 is an illustration of the Send_clk signal generation.

FIG. 5 is a flowchart illustrating fixed latency.

FIG. 6 is a flowchart illustrating the initialization process.

FIG. 7 is an illustration of a run mode to control mode multiplexing.

FIG. 8 is an illustration of a timing diagram of a temporal delay queue.

### DETAILED DESCRIPTION OF THE INVENTION

The invention is a method and apparatus for synchronizing source I/O without synchronizers using temporal delay queues. In the following description, numerous specific details are set forth to provide a more thorough description of embodiments of the invention. It is apparent, however, to one skilled in the art, that the invention may be practiced without these specific details. In other instances, well known features like the chip design and working logic of registers, flip-flops, latches, and multiplexers have not been described in detail so as not to obscure the invention.

Design Requirements

IOB is the input/output block. Each IOB is either connected to another IOB, or an Field Programmable Gate Array (FPGA) that acts as a point of control for the system. All chip-to-chip communication is carried out at an uniform system clock rate. This communication can be achieved by either using both edges of the system clock signal, or just one edge. Since the FPGA communicates using both edges of half a uniform system clock, and has an IOB interface similar to an ASIC interface, it can not only accept data at the system clock rate, but also simplifies the IOB design because no new components have to be added to synchronize it with the system clock.

Source synchronous clocking is chosen because not only is there a delay greater than one clock cycle between a signal from the output register in one chip and the input register in another, but some chips communicate over a backplane. Communicating over a backpane introduces an additional amount of latency for the signal to not only traverse between multiple chips on the backpane, but also between the backplanes themselves. Source synchronous clocking not only accommodates a propagation delay greater than one clock cycle, but can also scale with clock frequency. A source clock which is one half the system clock is sent along with the data when both edges of the system clock signal are used, and is used by the receiver to clock the data into a register at both edges of the Send_clk signal. In case just one edge of the system clock signal is used to clock the data, then the source clock is equal to the system clock. This data can now be transferred to another register synchronously using the local clock only if the phase relationship between the Send_clk and local clock is known, there is adequate setup time for the second register, and it is okay for the system to accept intermittent data. Since during run mode a continuous stream of valid data is required by the system, the above mentioned scheme does not work. Additionally, if the phase relationship is not known or varies, a metastable state where the receiving interface cannot distinguish between a high and low signal (between a one and a zero signal) can occur. One way to overcome this handicap is to use two flip-flops in series per bit to synchronize the data. But both these schemes incur an additional propagation delay that we saw earlier. A multi-entry TDQ is used instead to write the incoming data one full cycle before it is read out.

TDQ

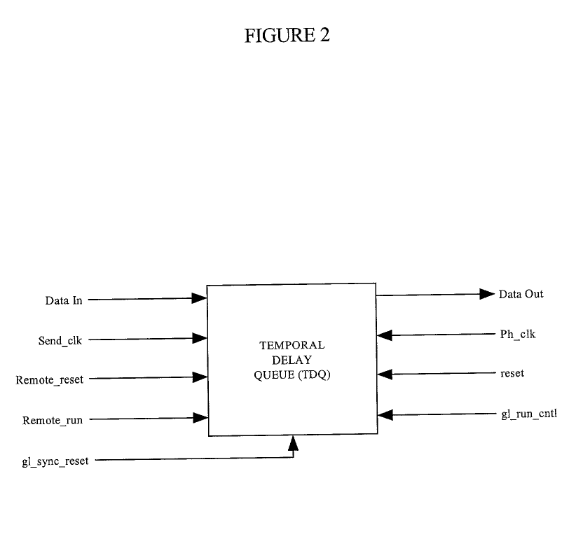

A TDQ is a collection of registers and latches. Each register in the queue has a unique address and is selected by an address pointer that can increment. Each register stores the incoming data and presents it to the receiving interface in phase with the local clock without the use of any synchronizers, and adjusts its internal delay in order to fool the software in seeing a fixed latency from the input of the sending IOB to the input of the TDQ for all paths, which provides a known, fixed latency for all IOB to IOB connections after reset. The number of registers depends on the latency tolerance of the system. A large number of registers means more tolerance to latency. If the number of registers increases, then the multiplexer size increases as well, and so does the rd_addr counter. FIG. 2 shows the input and output signals for a 4 entry TDQ. The input signals are Data In, Send_clk, Remote_reset, Remote_run, Ph_clk, reset, gl_sync_reset, and gl_run_cntl, and the output signal is Data Out. We will use a 4 entry TDQ as an example throughout this patent, but the entry size may vary depending on the system.

The depth of the fifo needs to match the maximum chip to chip latency so that any data in transit between chips can be stored in the queue when the system is stopped or switched from control mode to run mode. For a system that streams data all the time without stopping a four entry queue is sufficient for any chip to chip latency. The total latency taken modulo 4 becomes the residual latency which is used to program the queue pointers.

TDQ logic

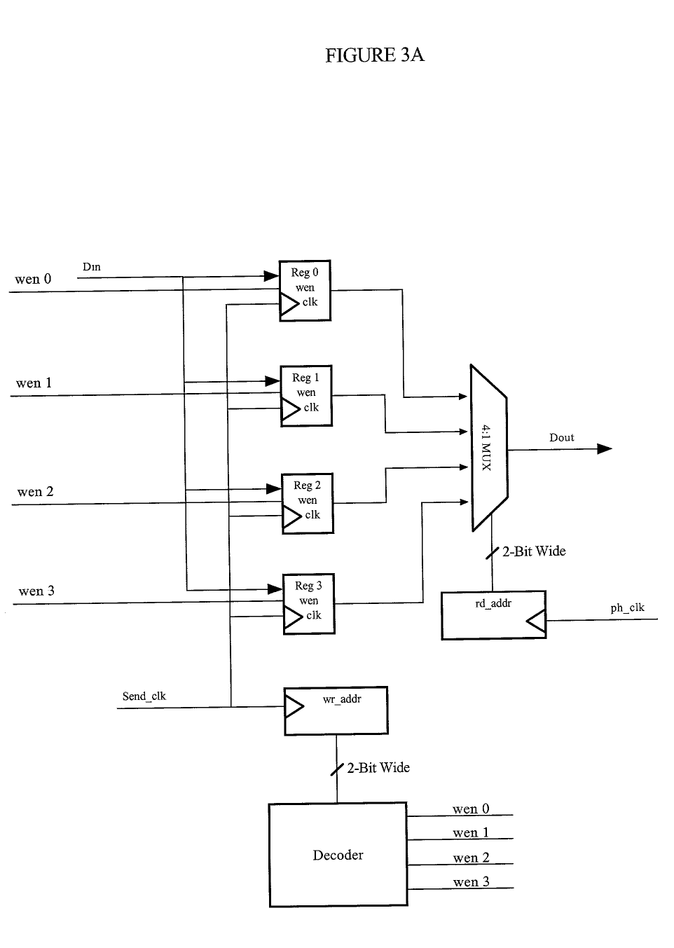

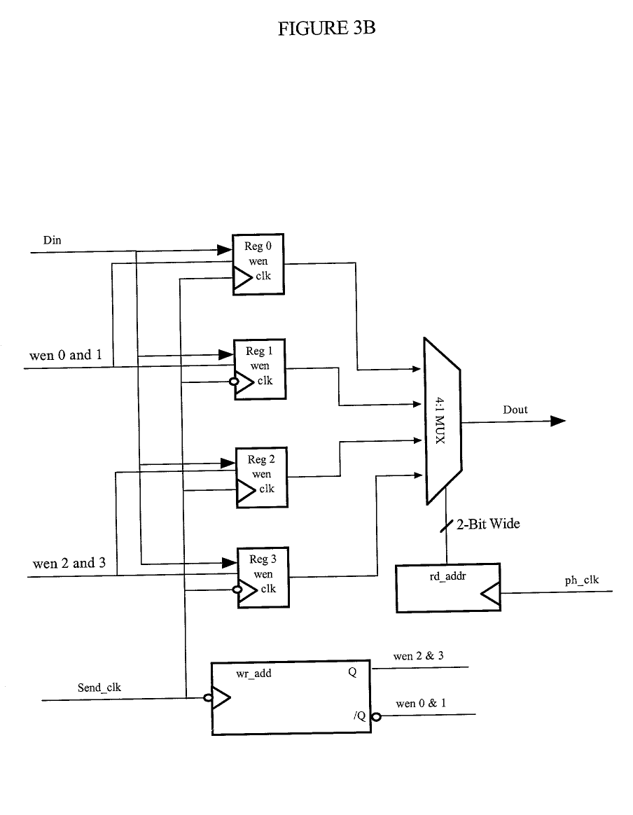

Data is written into a register using the Send_clk signal, and read out using a multiplexer controlled by a read address counter that is incremented independently by a separate local read clock. In one embodiment, since the TDQ is a 4 entry TDQ, the read address is 2 bits wide. FIG. 3A shows the TDQ logic, where data (Din) is sent in a queue of four registers: Reg 0 through Reg 3, which are controlled by the Send_clk signal. The rising edge of the Send_clk signal also increments the wr_addr counter that chooses one of the four registers as it gets incremented using Modulo 4 arithmetic. In other words, initially Reg 0 is chosen. On increment by one, Reg 1 is chosen. Next, its Reg 2's turn and finally its Reg 3's turn. On the next increment Modulo 4 gives zero, hence Reg 0 is once again chosen, and the cycle continues. The 2-bit wide output of the wr_addr counter is parsed by a decode block. The 2-bit wide rd_addr counter controls the 4:1 multiplexer which has the outputs of the four registers as its input and Dout as its output. The counter is incremented by the ph_clk signal.

FIG. 3B shows the TDQ logic, where data (Din) is sent in a queue of four registers: Reg 0 through Reg 3, which are controlled by the Send_clk signal. The wr_addr counter is incremented by the negative edge of the Send_clk signal. On the negative edge of the clock signal, either Reg 1 or Reg 3 is written. On the positive edge of the clock signal, either Reg 0 or Reg 2 is written. The 2-bit wide rd_addr counter controls the 4:1 multiplexer which has the outputs of the four registers as its input and Dout as its output. In operation, rd_addr will alternately select input from even registers on one ph_clk pulse set and odd registers on the next ph_clk pulse set.

In order to ensure valid data at the output, it is read out in the same order as it was written in. In other words, a FIFO (First In First Out) system is used. A fixed latency in reading out this data is maintained by initializing the read and write address counters to a fixed offset which is maintained throughout a given operation while the counters are incremented by their respective clocks. The offset between the read and write address is kept to a minimum of two locations to guarantee the read data stable before it is read out. Since latencies between chips vary, the present invention makes adjustments to this variable latency and presents them as a fixed latency equal to the longest delay that is encountered in the system. Alternately, software can program an IOB for a fixed latency that is shorter for a particular IOB to IOB interface.

There is no error detection logic built into the TDQ logic arising due to hardware malfunction. This means there is no detection for queue over and under runs under normal operation conditions, since these errors do not normally occur except if there is some kind of hardware malfunction. These errors, if they occur, can be detected by tag checking, and the error detection logic is hence not incorporated into the design of the present invention reducing overall latency of the entire system, and reducing operational costs.

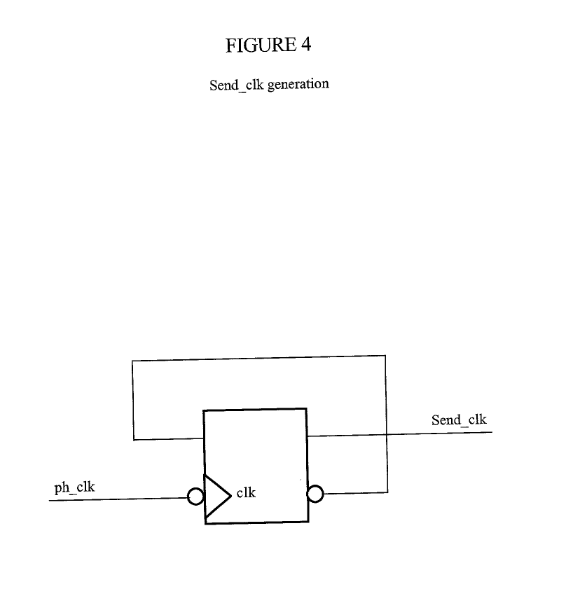

If data is clocked on both edges of half the uniform system clock cycle, an inverted version of the system clock is used to drive the divide by two Send_clk flip-flop in order for the send clock to transition in the center of the data eye pattern. The Send_clk flip-flop is reset for one cycle when the system reset signal is de-asserted. This is done in order to force a positive transition on the send clock immediately after reset is de-asserted. FIG. 4 shows an illustration of the generation of the half-frequency Send_clk signal.

Fixed Latency and Propagation Delay

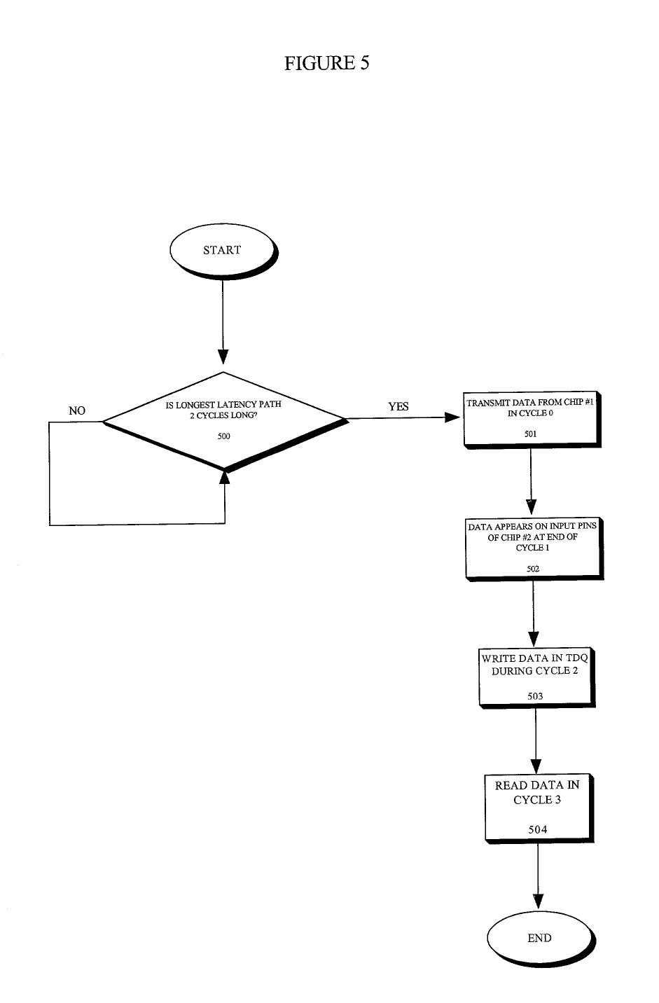

As mentioned earlier, the source synchronous TDQ logic provides a fixed total latency irrespective of the different latencies between various chips in the system. For a maximum of two cycles or less path, FIG. 5 shows an illustration of how a fixed latency of three is achieved. At step 500, the condition whether the IOB interface has a longest latency path of two cycles is checked. Since we are illustrating a maximum of 2 cycles, the system continues to check this condition till it is met. At step 501, if the condition is met, the data is transmitted from chip #1 in the first cycle, cycle 0. Next, at step 502, this data appears at the input pins of chip #2 at the end of the second cycle, cycle 1. At step 503 this data is written in the TDQ during the third cycle, cycle 2. Finally, at step 504 the written data is read out during the fourth cycle, cycle 3. This means that any cycle path needs an extra cycle of latency known as a guard band. This guard band is achieved by the Send_clk signal which is skewed so that it transitions close to the middle of the data eye pattern, or a little bit later in order to not only give the maximum margin for the skew with respect to the data, but also to maximize the setup and hold times at the receiving IOB.

The propagation delay is calculated using worst case operating conditions since these can vary during the operation, and also to insure that the maximum propagation delay value is used when computing programmed IOB latency values. These worst cases may include processes, voltage, and temperature. Since data is read out at a later time than is written in using a delay based on worst case operating conditions, changes in temperature and voltage should not affect the proper operation of the TDQ. A propagation delay based on worst case conditions plus a guard band insures that the read data is stable when it is read out under any conditions of temperature, voltage, or processes.

Initialization

The default value for the maximum chip-to-chip latency is used to initialize the offset between the read and write address counters at power on reset, or by asserting the gl_sync_reset signal. The default latency value for each IOB can be programmed by software which facilitates short intraboard paths with latency values less than the maximum default value. This default value is greater than or equal to the largest latency for any chip-to-chip path in the system.

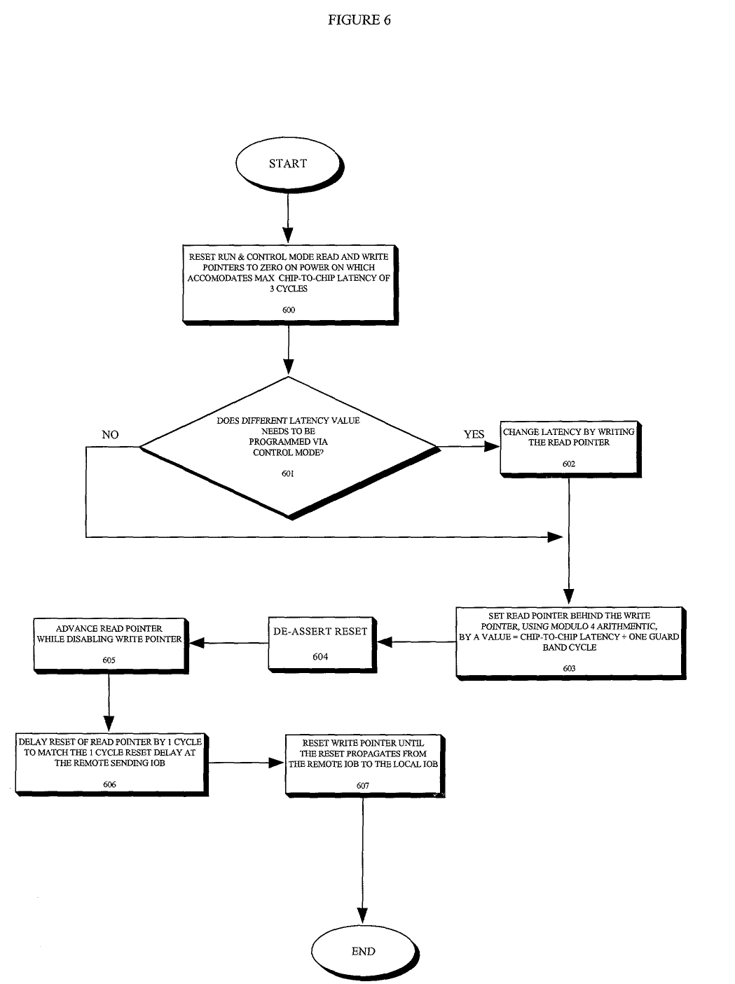

FIG. 6 is a flowchart that illustrates the initialization process, where at step 600 the run and control mode read and write pointers are set to zero on power on reset. This accommodates a maximum chip-to-chip latency of three cycles. Next, at step 601, the condition of whether a different latency value needs to be programmed via the control mode is checked. If the value needs to be changed, then at step 602 it is changed by writing the read pointer and go to step 603. If the value does not need to be altered, then at step 603 the read pointer is set behind the write pointer using modulo 4 arithmetic. This value is set equal to the latency between two consecutive chips plus one guard band cycle. Next, at step 604, the reset is de-asserted. Next, at step 605, the read pointer is advanced while the write pointer is disabled. At step 606, the reset of the read pointer is delayed by one cycle to match the one cycle reset delay at the remote sending IOB. Finally, at step 607, the write pointer stays reset until the reset propagates from the remote IOB to the local IOB.

For example, a chip-to-chip latency of two cycles would have the following transfer: reset is de-asserted at the remote sending IOB in cycle 0. The first data word is outputted at the output register at the beginning of cycle 1. This data word appears at the input pins of chip #2 at the end of cycle 2. The data gets written into the TDQ at location 0 sometime during cycle 3. During this time, the read pointer has incremented from its initial value of one to three. On the next read clock, the read pointer increments to zero using modulo 4 arithmetic, and the data word is read. Hence, there is a fixed latency of three that the software sees: chip-to-chip latency plus one extra clock cycle as a guard band.

In order for the IOB initialization to work, reset is released at all chips on all boards during the same system clock cycle, including all interfaces that communicate across the backpane. In addition to reset, gl_sync_reset also serves as an IOB reset signal while in control mode. In order for the local IOB to function correctly, the gl_sync_reset signal is asserted for several cycles so it can propagate across the interface. Since the valid bits are used by control mode, they are cleared as well. Additionally, since tag and parity checking are continuously performed during run mode, all TDQ entries are initialized with zero tags and good parity. Alternately, a null data word with valid parity is muxed into the data path during the first few cycles after reset.

Reset is first de-asserted on the local chip while advancing the read pointer. While in control mode, a special control code indicating reset is asserted on the bus that will reset the write pointer and keep it reset until reset is de-asserted first on the remote TDQ and later on the local TDQ. After a run mode to control mode transition (or vice-versa), the offset between the inactive read and write address pointers are the same as the original reset state. The read pointer, which is controlled by the local TDQ, stops first while the write pointer continues for one or two cycles more while the run signal propagates from the remote TDQ to the local TDQ. Likewise, the read pointer starts before the write pointer once the TDQ is enabled again. Since the two clocks are out of phase with respect to each other, the offset between the two counters can vary. For example, the offset could vary between the minimum value of one and an offset of two. At no time during data transfers should the offset be allowed to go to zero.

Run to Control Mode Switching (or Vice-versa)

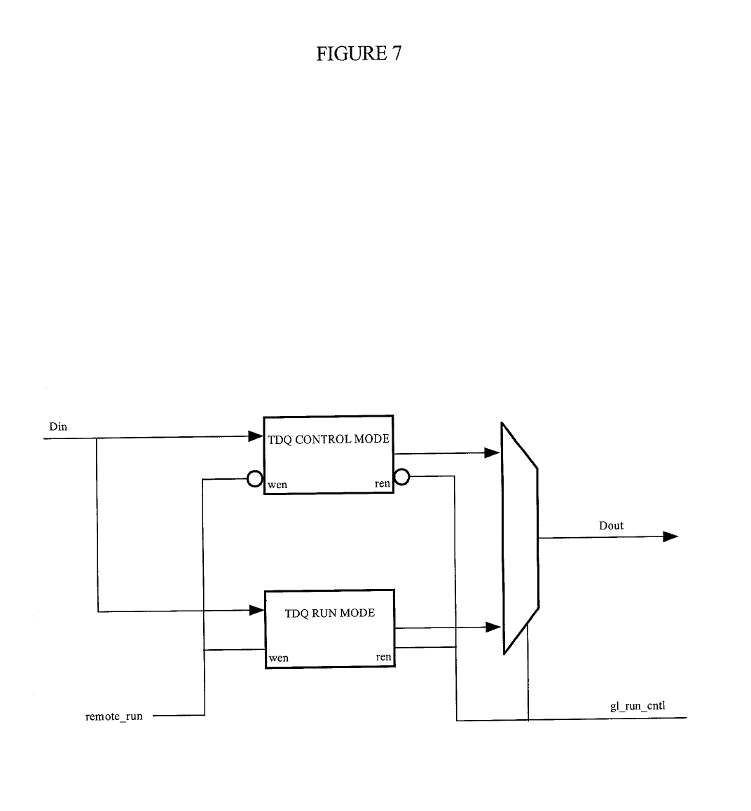

There are a separate set of TDQs for run and control modes. FIG. 7 shows an illustration of the switching between run and control modes (or vice-versa). The run and control delay queues are treated as a single entity with the remote_run signal being the high order address bit that selects between the two modes, but there is a separate set of read and write counters for both modes. In our example of a 4 entry TDQ seen in FIGS. 3A-B, a 2-bit address counter is required and is provided by the rd_addr counter. The run and control counters are continuously incremented by their respective clocks during run and control modes respectively. In order to differentiate the two modes, an extra signal, namely the remote_run signal is required on the interface for run mode. This signal is used to switch the receiving side of the TDQ between run and control mode. The gl_run_cntl signal controls the 2:1 multiplexer by either choosing the TDQ in run or control mode. Alternately, if the registers are implemented using a memory array, then the multiplexer is not needed, and the gl_run_cntl signal is used as the high order address bit.

Change of Latency During Control Mode

The latency value can be changed during the control mode by writing to the latency register. The TDQ counters are not updated at this point. The gl_sync_reset signal is used as a IOB reset signal during control mode. By asserting the gl_sync_reset signal during control mode, not only are both the control and run mode rd_addr counters are set to the programmed latency value, but the wr_addr counters are reset. De-assertion of the gl_sync_reset signal will start the rd_addr control mode counter in the local TDQ. Depending on the IOB latency, the wr_addr control mode counter will be enabled next. Hence, the latency value is changed without going through a global reset.

Temporal Delay Queue Timing

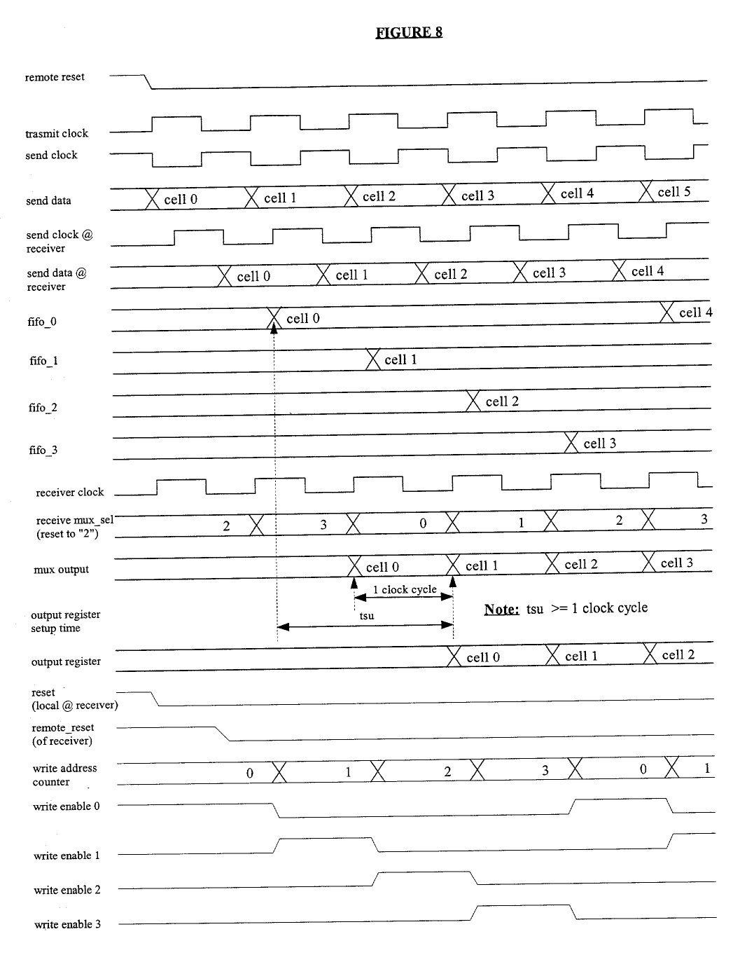

FIG. 8 shows one illustration of a TDQ timing diagram. Several key features of the TDQ and its logic is seen in this example, and include, a fixed latency for all paths. This fixed latency for all paths is possible because the frequency of the clock cycle of signals ‘transmit clock’, ‘send clock’, ‘send clock @ receiver’, and the ‘receiver clock’ are the same. In the example, the ‘remote reset’ signal is active high, and when the signal goes to “0” the entire procedure begins. The fixed latency is seen at the rising edge of each ‘transmit clock’ signal that drives the ‘send data’ signal which gets valid data in the respective cells. Hence at the first rising edge there is valid data in cell0, at the next rising edge there is valid data in cell1, and so on. Next, we see that the ‘send clock @ receiver’ signal is at a fixed delayed latency of ¾^{th} of the ‘send clock’ cycle, and this fixed delay is maintained, which is seen from the fixed amount of time valid data propagates from cell0 through cell4 in the ‘send data @ receiver’ signal, and the ‘fifo_0’ through ‘fifo_3’ signals. Signals ‘send clock’ and ‘receiver clock’ are mesosynchronous to each other. In other words, the two signals are out of phase with each other, but have the same frequency. In the example, one can see that the phase of the two signals are π/2 with respect to each other. The ‘mux_sel’ signal indicates when valid data is received at the ‘mux_output’ signal, and is reset to “2”. In the example, the first valid ‘mux_sel’ position (0) starts at the rising edge of the third ‘receive clock’ cycle and lasts for one cycle before it increments by one. The results of the ‘mux_sel’ signal is seen in the ‘mux_output’ signal where cell0 gets valid data when ‘mux_sel 0’ is shown, and so on.

The ‘setup time’ (tₛᵤ) is the duration from the start of valid data in cell0 seen at the ‘fifo_0’ signal to the end of cell0 seen at the ‘mux_output’ signal. This setup time, as explained earlier, is greater than or equal to one clock cycle of a TDQ. This valid data is seen in the cells one clock cycle after it appears in the respective cells in the ‘mux_output’ signal. The ‘local reset @ receiver’ signal is also active high, and when that signal goes to “0” it deasserts the ‘remote_reset’ signal of the receiver, which is an active high signal too, to go to “0” at the next falling edge of the ‘send clock @ receiver’ signal. Finally, the ‘write address counter’ signal shows the locations if the counters when valid data is written in them depending upon the active high ‘write enable’ signals. Hence, when the ‘write enable 0’ signal is high, valid data is written in the ‘write address counter 0’, and so on. The duration of the ‘write enable’ signals is consistent with the rest of the other signals in that it has a frequency of one clock cycle as determined by any of the above mentioned clock signals.

Thus, a method and apparatus for synchronizing source IO without synchronizers using temporal delay queues is described in conjunction with one or more specific embodiments. The invention is defined by the following claims and their full scope of equivalents.

We claim:

1. A method for synchronizing a source I/O block comprising:
using a temporal delay queue (TDQ) as a receiving device to store incoming data wherein said receiving device is in phase with a local clock;
presenting said incoming data to said receiving device using a pull model of data transmission in phase with said local clock using TDQ logic; and
initializing said TDQ logic at power on reset, or by asserting a signal.

2. The method of claim 1 wherein said incoming data is generated by an I/O block.

3. The method of claim 1 wherein said incoming data is generated by a Field Programmable Gate Array (FPGA).

4. The method of claim 1 wherein said incoming data is generated by a TDQ.

5. The method of claim 1 wherein a fixed latency is maintained between device generating said incoming data and said receiving device.

6. The method of claim 5 wherein said fixed latency is set as the default latency for said I/O block.

7. The method of claim 1 wherein said incoming data is in run mode or control mode wherein said incoming data is preserved even when said I/O block switches from one mode to another.

8. A computer program product comprising:
a computer usable medium having computer readable program code embodied therein configured to synchronize a source I/O block, said computer product comprising:
computer readable code configured to cause a computer to use a temporal delay queue (TDQ) as a receiving device to store incoming data wherein said receiving device is in phase with a local clock;
computer readable code configured to cause a computer to present said incoming data to said receiving device using a pull model of data transmission in phase with said local clock using TDQ logic; and
computer readable code configured to cause a computer to initialize said TDQ logic at power on reset, or by asserting a signal.

9. The computer program product of claim 8 wherein said incoming data is generated by an I/O block.

10. The computer program product of claim 8 wherein said incoming data is generated by a Field Programmable Gate Array (FPGA).

11. The computer program product of claim 8 wherein said incoming data is generated by a TDQ.

12. The computer program product of claim 8 wherein a fixed latency is maintained between device generating said incoming data and said receiving device.

13. The computer program product of claim 12 wherein said fixed latency is set as the default latency for said I/O block.

14. The computer program product of claim 8 wherein said incoming data is in run mode or control mode wherein said incoming data is preserved even when said I/O block switches from one mode to another.

15. An article of manufacture comprising:
a computer usable medium having computer readable program code embodied therein for synchronizing a source I/O block, said computer readable program code in said article of manufacture comprising:
computer readable program code configured to cause said computer to use a temporal delay queue (TDQ) as a receiving device to store incoming data wherein said receiving device is in phase with a local clock;
computer readable program code configured to cause said computer to present said incoming data to said receiving device using a pull model of data transmission in phase with said local clock sing TDQ logic; and
computer readable program code configured to cause said computer to initialize said TDQ logic at power on reset, or by asserting a signal.

16. The article of manufacture of claim 15 wherein said incoming data is generated by an I/O block.

17. The article of manufacture of claim 15 wherein said incoming data is generated by a Field Programmable Gate Array (FPGA).

18. The article of manufacture of claim 15 wherein said incoming data is generated by a TDQ.

19. The article of manufacture of claim 15 wherein a fixed latency is maintained between device generating said incoming data and said receiving device.

20. The article of manufacture of claim 19 wherein said fixed latency is set as the default latency for said I/O block.

21. The article of manufacture of claim 15 wherein said incoming data is in run mode or control mode wherein said incoming data is preserved when said I/O blocks.
